(19) United States
(12) Patent Application Publication
(10) Pub. No.: US 2007/0139034 A1
(43) Pub. Date: Jun. 21, 2007

(54) Semiconductor Device and Testing Method Thereof, and Resistance Measurement Apparatus

(75) Inventors: Shuichi Takada, Minato-ku, Tokyo (JP); Eisuke Tanaka, Minato-ku, Tokyo (JP); Takeshi Abiru, Minato-ku, Tokyo (JP)

Correspondence Address: BANNER & WITCOFF, LTD.;ATTORNEYS FOR CLIENT NO. 000449, 001701, 1100 13th STREET, N.W., SUITE 1200, WASHINGTON, DC, 20005-4051, US

(73) Assignee: KABUSHIKI KAISHA TOSHIBA, Tokyo (JP)

(21) Appl. No.: 11/608,298

(22) Filed: Dec. 8, 2006

(30) Foreign Application Priority Data
Dec. 9, 2005 (JP) 2005-355925

(51) Int. Cl. G01R 31/28

(52) U.S. Cl. 324/158.1

(57) ABSTRACT

According to the present invention, there is provided a semiconductor device having: a switching element serially connected to a resistive element to be measured; a plurality of transistors respectively connected in parallel to a series circuit consisting of the resistive element to be measured and the switching element, which will respectively take desired resistance values when turned on; and a measurement section which measures a resistance value of a parasitic resistance which occurs so as to be coupled to the resistive element to be measured by turning off the switching element and then controlling switching operations of the plurality of transistors to change the resistance values of resistors formed by the plurality of transistors, and subsequently measures a resistance value of the resistive element to be measured based on a resistance value of the parasitic resistance by turning on the switching element while turning off the plurality of transistors.

### CROSS REFERENCE TO RELATED APPLICATIONS

This application is based upon and claims the benefit of priority under 35 USC 119 from the Japanese Patent Application No. 2005-355925, filed on Dec. 9, 2005, the entire contents of which are incorporated herein by reference.

### BACKGROUND OF THE INVENTION

The present invention relates to a semiconductor device and a testing method thereof, and a resistance measurement apparatus.

Production testing prior to shipment may include wafer tests, which are electrical tests performed in the form of a wafer on a plurality of silicon chips formed on a wafer after conclusion of front-end processing for the purpose of selecting good chips, and final tests, which are electrical tests performed on IC chips obtained by dicing and incorporating the selected good chips into packages.

In some cases, such production testing may involve measuring a total resistance value of respective resistors formed on a silicon chip. This measurement is performed by connecting a tester to the silicon chip to be measured, applying a desired voltage thereto, and measuring a current flowing through the silicon chip.

In this case, the measurement represents a combined value of a total resistance value of respective resistors formed within the silicon chip and a total resistance value of parasitic resistances occurring between the silicon chip and the tester.

In recent years, lower levels in the total resistance value of respective resistors formed within silicon chips have lead to a problem in that, if a total resistance value of parasitic resistances is high between the silicon chip and the tester, accurate measurement of the total resistance value of respective resistors formed in the silicon chip cannot be accomplished.

The following is a patent document related to a contact resistance measurement element.

Japanese Patent Laid-Open No. 4-316344.

### SUMMARY OF THE INVENTION

A semiconductor device according to an aspect of the present invention includes:

a switching element serially connected to a resistive element to be measured;

a plurality of transistors respectively connected in parallel to a series circuit consisting of the resistive element to be measured and the switching element, which will respectively take desired resistance values when turned on; and

a measurement section which measures a resistance value of a parasitic resistance which occurs so as to be coupled to the resistive element to be measured by turning off the switching element and then controlling switching operations of the plurality of transistors to change the resistance values of resistors formed by the plurality of transistors, and subsequently measures a resistance value of the resistive element to be measured based on a resistance value of the parasitic resistance by turning on the switching element while turning off the plurality of transistors.

A semiconductor device testing method according to an aspect of the present invention, which tests a semiconductor device having

a switching element serially connected to a resistive element to be measured, and

a plurality of transistors respectively connected in parallel to a series circuit consisting of the resistive element to be measured and the switching element, which will respectively take desired resistance values when turned on, the testing method includes:

measuring a resistance value of a parasitic resistance which occurs so as to be coupled to the resistive element to be measured by turning off the switching element and controlling switching operations of the plurality of transistors to change the resistance values of resistors formed by the plurality of transistors; and

measuring a resistance value of the resistive element to be measured based on a resistance value of the parasitic resistance by turning on the switching element while turning off the plurality of transistors.

### BRIEF DESCRIPTION OF THE DRAWINGS

FIG. 1 is a circuit diagram showing a configuration of a resistance measurement apparatus according to a first embodiment of the present invention;

FIG. 2 is a circuit diagram showing a configuration of a resistance measurement apparatus according to a second embodiment of the present invention; and

FIG. 3 is an explanatory diagram showing a relationship between a number of MOS transistors which have been turned on, and a current value “I” flowing through a resistance measurement apparatus.

### DETAILED DESCRIPTION OF THE INVENTION

Embodiments of the present invention will now be described with reference to the drawings.

### (1) FIRST EMBODIMENT

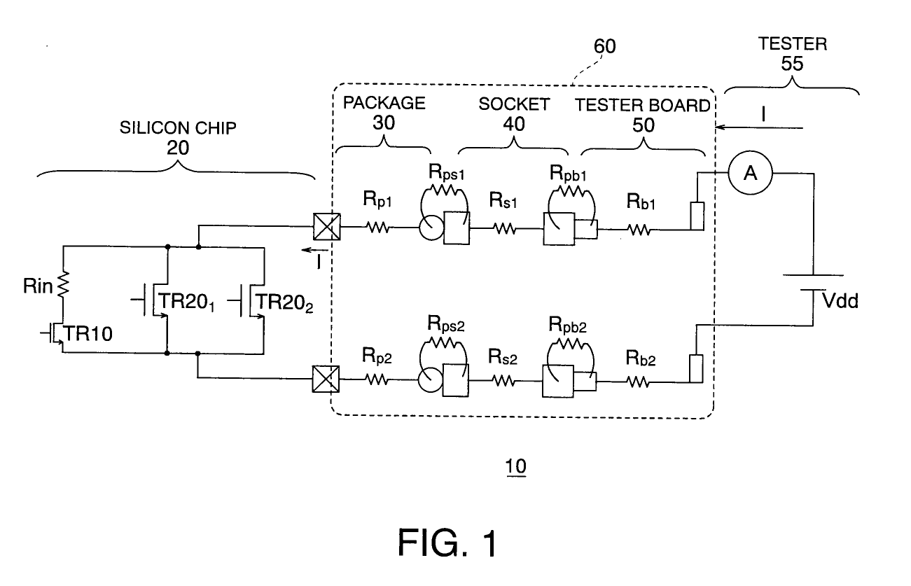

A configuration of a resistance measurement apparatus 10 according to a first embodiment of the present invention is shown in FIG. 1. The resistance measurement apparatus 10 is used in final tests which test IC chips obtained by dicing and incorporating the good chips selected through wafer tests into packages are electrically tested.

More specifically, the resistance measurement apparatus 10 is formed by connecting a package 30 having a silicon chip 20 incorporated therein to a socket 40 placed on a tester board 50. Additionally, a tester 55 is connected to the tester board 50. A plurality of resistors having desired resistance values are formed in the silicon chip 20. An internal resistor “Rin” represents a combined resistor of these resistors. Therefore, the resistance value of the internal resistor “Rin” represents the resistance value of the combined resistor of the respective resistors formed in the silicon chip 20.

A MOS transistor TR10 as a switching element is serially connected to the internal resistor “Rin” to be measured. MOS transistors TR20₁ and TR20₂, having the same transistor characteristics, are parallel-connected to the series circuit consisting of the internal resistor “Rin” and the MOS transistor TR10.

In the present embodiment, the package 30 includes package resistors Rp1 and Rp2 as parasitic resistances, the socket 40 includes socket resistors Rs1 and Rs2 as parasitic resistances, while the tester board 50 includes board resistors Rb1 and Rb2 as parasitic resistances. In addition, contact resistors Rps1 and Rps2 exist as parasitic resistances between the package 30 and the socket 40, while contact resistors Rsb1 and Rsb2 exist as parasitic resistances between the socket 40 and the tester board 50.

The resistance measurement apparatus 10 measures a resistance value of the internal resistor “Rin”, which is a combined resistor of each resistor formed within the silicon chip 20 to be measured by applying a voltage “Vdd” to the silicon chip 20, and measuring a current “I” which flows through the silicon chip 20.

More specifically, the MOS transistor TR10 is initially turned off to create a state in which the internal resistor “Rin” is not connected. Next, a drain-source voltage, i.e., the voltage “Vdd”, to be applied between the drains and the sources of the MOS transistors TR20₁ and TR20₂ are adjusted so that the MOS transistors TR20₁ and TR20₂ respectively take a desired resistance value “Rtr” when turned on.

Generally, MOS transistors TR20₁ and TR20₂ each have a linear region in which a current value flowing between the drain and the source increases so as to have a constant gradient (i.e. resistance value “Rtr”) as the drain-source voltage increases, and a region in which a constant value is approximately maintained after the current reaches the constant value. In the case of the present embodiment, drain-source voltage is adjusted within the range of the linear region.

Next, the MOS transistor TR20₁ is turned on while the MOS transistor TR20₂ is turned off in order to measure a current “I1” flowing through the resistance measurement apparatus 10. A resistance value “R1” of the combined resistor of the entire resistance measurement apparatus 10 in a state in which only the MOS transistor TR20₁ is turned on may be expressed using voltage “Vdd” and current “I1” by the formula.
R132 Vdd/I1 (1)

In the resistance measurement apparatus 10, if “Rex” represents a total resistance value of an external parasitic resistance existing on the exterior 60 of the silicon chip 20, then the total value “Rex” may be expressed by the formula,
Rex=R1−Rtr/1 (2)
where the denominator of the resistance value “Rtr”, namely “1”, represents the number of the MOS transistor TR20₁ that has been turned on.

Subsequently, both MOS transistors TR20₁ and TR20₂ are turned on to measure a current “I2” flowing through the resistance measurement apparatus 10. A resistance value “R2” of the combined resistor of the entire resistance measurement apparatus 10 in a state in which both MOS transistors TR20₁ and TR20₂ are turned on may be expressed using voltage “Vdd” and current “I2” by the formula.
R2=Vdd/I2 (3)

The total resistance value “Rex” of the external parasitic resistance may be expressed in a similar manner to the above-provided Formula 2 by the formula,
Rex=R2−Rtr/2 (4)
where the denominator of the resistance value “Rtr”, namely “2”, represents the number of MOS transistors TR20₁ and TR20₂ that have been turned on.

Eliminating the total resistance value “Rex” of the external parasitic resistance from the Formulas 2 and 4 results in the formula
R1−Rtr/1=R2−Rtr/2 (5)
being true, which may be re-written as the formula.
Rtr=(R1=R2)×2 (6)

Next, the resistance value “R1” of the combined resistor of the entire resistance measurement apparatus 10 in a state in which only the MOS transistor TR20₁ is turned on is calculated using the Formula 1 provided above, while the resistance value “R2” of the combined resistor of the entire resistance measurement apparatus 10 in a state in which both MOS transistors TR20₁ and TR20₂ are turned on is calculated using the Formula 3 provided above.

By substituting the calculated resistance values “R1” and “R2” into the above-described Formula 6, a resistance value “Rtr” is calculated for the MOS transistors TR20₁ and TR20₂ which have been turned on after adjusting the drain-source voltage. Then, by substituting the resistance value “Rtr” into the above-described Formula 4, the total resistance value “Rex” of the external parasitic resistance is calculated.

As a result, when the total resistance value “Rex” of the parasitic resistance is smaller than a predetermined value, the MOS transistor TR10 is turned on while the MOS transistors TR20₁ and TR20₂ are turned off. Subsequently, by measuring a current “I” flowing through the resistance measurement apparatus 10, the resistance value of the combined resistor of the entire resistance measurement apparatus 10 is calculated. The resistance value of the internal resistor “Rin” formed within the silicon chip 20 is calculated by subtracting the total resistance value “Rex” of the external parasitic resistance existing on the exterior 60 of the silicon chip 20 from the calculated resistance value of the combined resistor of the entire resistance measurement apparatus 10.

Therefore, in the present embodiment, an IC chip (silicon chip 20 and package 30) placed on the socket 40 need not be replaced when, for instance, measuring the total resistance value “Rex” of the external parasitic resistance and then measuring the resistance value of the internal resistor “Rin”. This prevents changes in the resistance values of the contact resistors Rps and Rsb, thereby enabling resistance values of the internal resistor “Rin” to be measured in a more accurate manner.

In contrast, when the total resistance value “Rex” of the parasitic resistance is greater than a predetermined value, the resistance values of the contact resistors Rps and Rsb are determined to be high. In this case, reconnection and subsequent re-measurement is performed.

As seen, according to the present embodiment, the accuracy of resistance value measurement performed on the internal resistor “Rin” formed in the silicon chip 20 may be improved. Therefore, determination of good/bad products may be conducted in a more accurate manner.

In addition, according to the present embodiment, it is suffice to add MOS transistors TR10, TR20₁ and TR20₂ to the inherent circuit elements of the silicon chip 20. This enables measurement to be performed using a simpler configuration.

### (2) SECOND EMBODIMENT

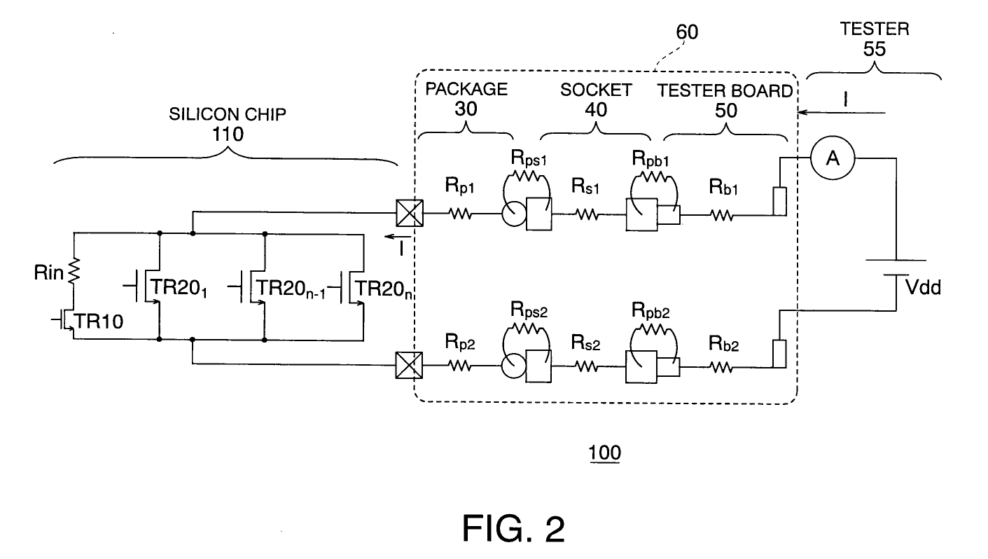

A configuration of a resistance measurement apparatus 100 according to a second embodiment of the present invention is shown in FIG. 2. In a silicon chip 110 of the present embodiment, a MOS transistor TR10 is serially connected to the internal resistor “Rin” to be measured, while three or more MOS transistors TR20₁ to TR20ₙ, having the same transistor characteristics, are parallel-connected to the series circuit consisting of the internal resistor “Rin” and the MOS transistor TR10. With the exception of the silicon chip 110, components of the resistance measurement apparatus 100 are the same as the components shown in FIG. 1. Therefore, like reference numerals will be assigned thereto, and descriptions thereon will be omitted.

A method for measuring a resistance value of an internal resistor “Rin”, which is a combined resistor of respective resistors formed within the silicon chip 110 to be measured, will now be described.

First, in the same manner as in the first embodiment, the MOS transistor TR10 is turned off to create a state in which the internal resistor “Rin” is not connected. Next, a drain-source voltage, i.e. the voltage “Vdd”, is adjusted so that the MOS transistors TR20₁ to TR20ₙ respectively take a desired resistance value “Rtr” when turned on.

Subsequently, the MOS transistors TR20₁ to TR20ₙ are all turned on to measure a current “Iₙ” flowing through the resistance measurement apparatus 100. A resistance value “Rₙ” of the combined resistor of the entire resistance measurement apparatus 100 in a state in which all MOS transistors TR20₁ to TR20ₙ are turned on may be expressed using voltage “Vdd” and current “Iₙ” by the formula
Rn=Vdd/In (7)

In the resistance measurement apparatus 100, if “Rex” represents a total resistance value of an external parasitic resistance existing on the exterior 60 of the silicon chip 110, then “Rex” may be expressed by the formula,
Rex=Rn−Rtr/n (8)
where the denominator of the resistance value “Rtr”, namely “n”, represents the number of MOS transistors TR20₁ to TR20ₙ that have been turned on.

Next, the MOS transistor TR20ₙ is turned off, and a current “Iₙ₋₁” flowing through the resistance measurement apparatus 100 in a state in which MOS transistors TR20₁ to TR20ₙ₋₁ are turned on is measured. A resistance value “Rₙ₋₁” of the combined resistor of the entire resistance measurement apparatus 100 in a state in which the MOS transistors TR201 to TR20ₙ₋₁ are turned on may be expressed using voltage “Vdd” and current “Iₙ₋₁” by the formula.
Rₙ₋₁=Vdd/Iₙ₋₁ (9)

The total resistance value “Rex” of the external parasitic resistance may be expressed in a similar manner to the above-provided Formula 8 by the formula,
Rex=Rₙ₋₁−Rtr/(n−1) (10)
where the denominator of the resistance value “Rtr”, namely “n−1”, represents the number of MOS transistors TR20₁ to TR20ₙ₋₁ that have been turned on.

Eliminating the total resistance value “Rex” of the external parasitic resistance from the Formulas 8 and 10 results in the formula,
Rₙ₋₁−Rtr/(n−1)=Rn−Rtr/n (11)
being true, which may be re-written as the formula.
Rtr=(Rₙ₋₁−Rn)/(1/(n−1)−1/n) (12)

Next, the resistance value “Rₙ” of the combined resistor of the entire resistance measurement apparatus 100 in a state in which all the MOS transistors TR20₁ to TR20ₙ are turned on is calculated using the Formula 7 provided above, while the resistance value “Rₙ₋₁” of the combined resistor of the entire resistance measurement apparatus 100 in a state in which the MOS transistors TR20₁ to TR20ₙ₋₁ are turned on is calculated using the Formula 9 provided above.

By substituting the calculated resistance values “Rₙ” and “Rₙ₋₁” to the above-described Formula 12, the resistance value “Rtr” is calculated for the MOS transistors TR20₁ to TR20ₙ which have been turned on after adjusting the drain-source voltage. Then, by substituting the resistance value “Rtr” to the above-described Formula 10, the total resistance value “Rex” of the external parasitic resistance is calculated.

As a result, when the total resistance value “Rex” of the parasitic resistance is smaller than a predetermined value, the MOS transistor TR10 is turned on while the MOS transistors TR20₁ to TR20ₙ are turned off. Subsequently, by measuring a current “I” flowing through the resistance measurement apparatus 100, the resistance value of the combined resistor of the entire resistance measurement apparatus 100 is calculated. The resistance value of the internal resistor “Rin” formed within the silicon chip 110 is calculated by subtracting the total resistance value “Rex” of the external parasitic resistance existing on the exterior 60 of the silicon chip 110 from the calculated resistance value of the combined resistor of the entire resistance measurement apparatus 100.

Therefore, in the present embodiment, an IC chip (silicon chip 110 and package 30) placed on the socket 40 need not be replaced when, for instance, measuring the resistance value of the internal resistor “Rin”, as was the case with the first embodiment. This prevents changes in the resistance values of the contact resistors Rps and Rsb, thereby enabling resistance values of the internal resistor “Rin” to be measured in a more accurate manner.

In contrast, when the total resistance value “Rex” of the parasitic resistance is greater than a predetermined value, the resistance values of the contact resistors Rps and Rsb are determined to be high. In this case, reconnection and subsequent re-measurement is performed.

As seen, according to the present embodiment, the accuracy of resistance value measurement performed on the internal resistor “Rin” formed in the silicon chip 110 may be improved. Therefore, determination of good/bad products may be conducted in a more accurate manner, as was the case with the first embodiment.

As performed in the present embodiment, by respectively parallel-connecting three or more MOS transistors TR20₁ to TR20ₙ to a series circuit consisting of an internal resistor “Rin” and a MOS transistor TR10, accuracy of resistance value measurement performed on the internal resistor “Rin” may be further improved in comparison to the first embodiment in which two MOS transistors TR20₁ and TR20₂ are parallel-connected, even in the event that the resistance values “Rtr” of the MOS transistors TR20₁ to TR20ₙ, which have been turned on, are dispersed.

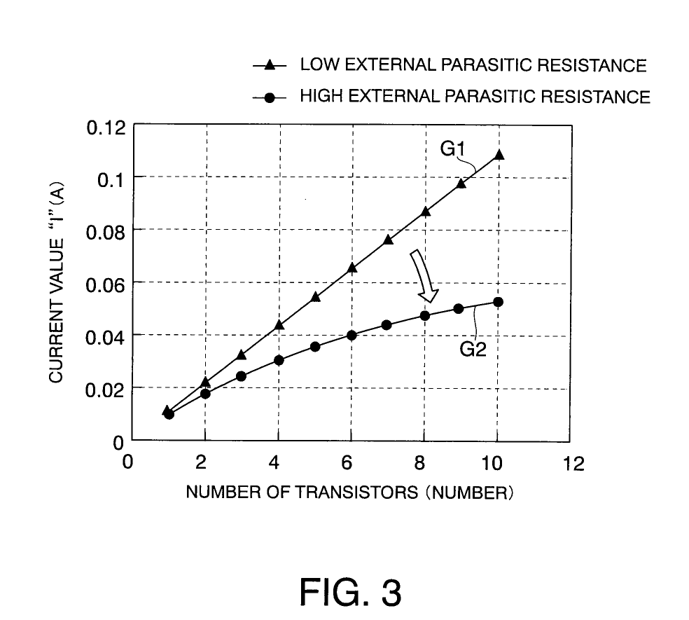

A relationship between a number of MOS transistors TR20₁ to TR20ₙ which have been turned on, and a current value “I” flowing through a resistance measurement apparatus 100 is shown in FIG. 3. As shown, when the total resistance value “Rex” of the external parasitic resistance is significantly smaller than the resistance value “Rtr” of the MOS transistors TR20₁ to TR20ₙ which have been turned on, a graph G1 resembles a straight line.

In contrast, when the total resistance value “Rex” of the external parasitic resistance is significantly greater than the resistance value “Rtr”, a graph G2 resembles a curved line. The rate of increase of the current value “I” is reduced even when the number of MOS transistors TR20₁ to TR20ₙ to be turned on is increased.

Therefore, for instance, when performing a test to merely determine whether the total resistance value “Rex” of the external parasitic resistance is greater than a predetermined value, such a test may be performed in a simple manner based on the curvature of the graphs shown in FIG. 3, without having to measure the total resistance value “Rex” of the external parasitic resistance.

The above-described embodiments are merely examples, and therefore do not limit the present invention. For instance, the method of measuring a resistance value of internal resistors “Rin”, formed within the silicon chips 20 and 110 to be measured, may be used when executing wafer tests instead of final tests.

What is claimed is:

1. A semiconductor device, comprising:
a switching element serially connected to a resistive element to be measured;
a plurality of transistors respectively connected in parallel to a series circuit consisting of the resistive element to be measured and the switching element, which will respectively take desired resistance values when turned on; and
a measurement section which measures a resistance value of a parasitic resistance which occurs so as to be coupled to the resistive element to be measured by turning off the switching element and then controlling switching operations of the plurality of transistors to change the resistance values of resistors formed by the plurality of transistors, and subsequently measures a resistance value of the resistive element to be measured based on a resistance value of the parasitic resistance by turning on the switching element while turning off the plurality of transistors.

2. The semiconductor device according to claim 1, wherein the measurement section adjusts drain-source voltage applied between the drains and sources of the plurality of transistors within a range of a linear region in which a current value flowing between the drains and sources increases at a constant gradient as the drain-source voltage increases.

3. The semiconductor device according to claim 1, wherein the measurement section changes a resistance value of resistors formed by the plurality of transistors by turning off the switching element and changing the number of transistors which have been turned on among the plurality of transistors.

4. The semiconductor device according to claim 1, wherein the measurement section measures a resistance value of the resistive element to be measured when the resistance value of the parasitic resistance is smaller than a predetermined value.

5. The semiconductor device according to claim 1, wherein the measurement section performs reconnection and re-measurement when the resistance value of the parasitic resistance is greater than a predetermined value.

6. The semiconductor device according to claim 1, wherein the measurement section determines whether a resistance value of the parasitic resistance is higher than a predetermined value by analyzing the relationship between the number of the transistors that have been turned on among the plurality of transistors, and a current flowing through the semiconductor device.

7. The semiconductor device according to claim 6, wherein the measurement section determines whether a resistance value of the parasitic resistance is higher than a predetermined value based on the rate of increase of the current flowing through the semiconductor device.

8. The semiconductor device according to claim 1, wherein the resistive element to be measured, the switching element and the plurality of transistors are formed on a same semiconductor chip.

9. The semiconductor device according to claim 8, wherein the resistive element to be measured is comprised of a combined resistor of a plurality of resistors formed on the semiconductor chip.

10. The semiconductor device according to claim 1, wherein the plurality of transistors share the same transistor characteristics.

11. The semiconductor device according to claim 1, wherein the measurement section comprises a tester, a tester board to which the tester is connected, and a socket placed on the tester board.

12. The semiconductor device according to claim 1, wherein the switching element is formed by a transistor.

13. A semiconductor device testing method for testing a semiconductor device which includes
a switching element serially connected to a resistive element to be measured, and
a plurality of transistors respectively connected in parallel to a series circuit consisting of the resistive element to be measured and the switching element, which will respectively take desired resistance values when turned on, the testing method comprising:
measuring a resistance value of a parasitic resistance which occurs so as to be coupled to the resistive element to be measured by turning off the switching element and controlling switching operations of the plurality of transistors to change the resistance values of resistors formed by the plurality of transistors; and
measuring a resistance value of the resistive element to be measured based on a resistance value of the parasitic resistance by turning on the switching element while turning off the plurality of transistors.

14. The testing method for testing a semiconductor device according to claim 13, wherein, when measuring a resistance value of the parasitic resistance, the drain-source voltage applied between the drains and sources of the plurality of transistors is adjusted within a range of a linear region in which a current value flowing between the drains and sources increases at a constant gradient as the drain-source voltage increases.

15. The testing method for testing a semiconductor device according to claim 13, wherein, when measuring a resistance value of the parasitic resistance, the resistance value of resistors formed by the plurality of transistors is changed by turning off the switching element and changing the number of transistors which have been turned on among the plurality of transistors.

16. The testing method for testing a semiconductor device according to claim 13, wherein, when measuring a resistance value of the resistive element to be measured, measurement of the resistance value of the resistive element to be measured is performed when the resistance value of the parasitic resistance is smaller than a predetermined value.

17. The testing method for testing a semiconductor device according to claim 13, wherein, when measuring a resistance value of the resistive element to be measured, reconnection and re-measurement is performed when the resistance value of the parasitic resistance is greater than a predetermined value.

18. The testing method for testing a semiconductor device according to claim 13, wherein, when measuring a resistance value of the parasitic resistance, determination is made on whether a resistance value of the parasitic resistance is higher than a predetermined value by analyzing the relationship between the number of the transistors that have been turned on among the plurality of transistors, and a current flowing through the semiconductor device.

19. The testing method for testing a semiconductor device according to claim 18, wherein, when measuring a resistance value of the parasitic resistance, determination is made on whether a resistance value of the parasitic resistance is higher than a predetermined value based on the rate of increase of the current flowing through the semiconductor device.

20. A resistance measurement apparatus, comprising:
a silicon chip on which
a switching element serially connected to a resistive element to be measured, and
a plurality of transistors respectively connected in parallel to a series circuit consisting of the resistive element to be measured and the switching element, which will respectively take desired resistance values when turned on, are formed;
a package into which the silicon chip is incorporated; and
a tester connected to the package sequentially via a socket and a tester board, which measures a resistance value of a parasitic resistance, occurring so as to be coupled to the resistive element to be measured, by turning off the switching element and controlling switching operations of the plurality of transistors to change the resistance values of resistors formed by the plurality of transistors, and subsequently measures a resistance value of the resistive element to be measured based on a resistance value of the parasitic resistance by turning on the switching element while turning off the plurality of transistors.
